(19) United States
(12) Patent Application Publication
(10) Pub. No.: US 2012/0138796 A1
(43) Pub. Date: Jun. 7, 2012

(54) Signal Processing Method for Charged Particle Beam Device, and Signal Processing Device

(75) Inventors: Fumihiro Sasajima, Hitachinaka (JP); Katsumi Setoguchi, Hitachinaka (JP)

(73) Assignee: Hitachi High-Technologies Corporation, Minat0-ku ,Tokyo (JP)

(21) Appl. No.: 13/390,415

(22) PCT Filed: Aug. 23, 2010
(86) PCT No.: PCT/JP2010/005159

§ 371 Date: Feb. 14, 2012

(51) Int. Cl. H01J 37/26

(52) U.S. Cl. 250/311

(57) ABSTRACT

Provided is a signal processing method for a charged particle beam, and a signal processing device, wherein the amount of beam radiation per unit area is restricted, while maintaining the magnifications in the X and Y directions constant. Proposed, in order to achieve the above-mentioned purpose, is a signal processing method and a signal processing device wherein a plurality of images taken at different places are added up, and an image is formed. Proposed as a specific example is a signal processing method and a signal processing device that obtains a repeating pattern formed on a sample and having the same shape or similar shapes, by moving the field of view, and that forms an image (or a signal waveform) by adding up the obtained signal, and conducts measurements using this image.

### TECHNICAL FIELD

The present invention relates to a signal processing method and a signal processing device for a charged particle beam device and, more particularly, to a signal processing method and a signal processing device in which a plurality of signals are accumulated and measurement of patterns and the like are conducted based on the accumulated signal.

### BACKGROUND ART

In a charged particle beam device represented by a scanning electron microscope, a finely focused charged particle beam is scanned on a sample to obtain desired information (for example, a sample image) from the sample. In such a charged particle beam device, resolution has been getting higher year by year and with higher resolution necessary observation magnification has been increasing. Further, as a beam scanning method for obtaining a sample image, there is a method as explained in Patent Literature 1 in which a plurality of images acquired through scanning of plural times are accumulated to acquire a final objective image.

On the other hand, micromachining of a surface of a semiconductor has been advancing to further refinement and a photo-resist which reacts with, for example, argon-fluoride (ArF) excimer laser beam (hereinafter referred to “ArF resist”) has been used as a photosensitive material for photolithography. The ArF laser beam has a short wavelength of 160 nm and, therefore, the ArF resist is considered suitable for light exposure for finer circuit patterns. It is known, however, that the ArF resist is so frail to electron beam irradiation that, when an electron beam is scanned on a formed pattern, acrylic resin or the like undergoes condensation reaction to reduce in its volume (hereinafter, called “shrink”) and a shape of a circuit pattern changes.

For suppressing the shrink of a pattern on a sample represented by an ArF resist, in Patent Literature 2 a technique of suppressing the amount of irradiation per unit area on a sample is explained in which a spacing between scanning lines of an electron beam is enlarged and a length in the Y direction becomes longer than a length in the X direction in a scanning area so that the scanned area becomes rectangular.

### CITATION LIST

### Patent Literature

Patent Literature 1: WO 2003/044821
Patent Literature 2: WO 2003/021186

### SUMMARY OF INVENTION

### Technical Problem

As explained in Patent Literature 1, by accumulating a plurality of images, an image having a high S/N ratio or the like can be formed but, as the number of cumulative sheets increases, the amount of shrink or the like increases correspondingly. For such a shrink or the like, the beam irradiation amount per unit area is conceivably suppressed by lowering a magnification in the Y direction as explained in Patent Literature 2. In the method, however, the scanning area must be expanded in the direction of spacings between scanning lines (the Y direction) and a ratio of the amounts of the signals of edges of the X direction and the Y direction changes. Especially, in the case of a circular pattern (for example, a contact hole), there is a possibility that a vertical and lateral shape changes. Further, when an image is formed for focusing, the sharpness or the like in a direction of a low magnification is lowered and, therefore, it is desired to make magnifications for a field of view (FOV) are constant in vertical and lateral directions.

A signal processing method and a signal processing device used for a charged particle beam device or the like for the purpose of suppressing the beam irradiation amount per unit area while keeping magnifications in the X direction and the Y direction (or lengths of a scanning area in the X direction and the Y direction) constant is hereinafter described.

### Solution to Problem

To accomplish the above objective, a signal processing method and a signal processing device for forming an image by accumulating a plurality of images at different positions is proposed. As a specific example, a signal processing method and a signal processing device is proposed in which a repetitive pattern of identical or similar shapes formed on a sample is acquired by moving a field of view, an image (or a signal waveform) is formed by accumulating acquired signals, and measurement or the like is executed by using the image.

### Advantageous Effects of the Invention

According to the above configuration, formation of a signal waveform or an image formed based on scanning of a charged particle beam can be implemented with high precision while the beam irradiation amount per unit area is suppressed.

### BRIEF DESCRIPTION OF DRAWINGS

FIG. 1 is a flowchart for explaining processing steps from setting of measurement/inspection conditions to measurement/inspection;

FIG. 2 is a diagram for explaining examples in which a plurality of FOV's are set on line patterns;

FIG. 3 is a diagram for explaining examples in which a plurality of FOV's are set on a plurality of hole patterns;

FIG. 4 shows flowcharts for explaining focusing processing steps;

FIG. 5 shows flowcharts for explaining positioning condition setting steps;

FIG. 6 shows flowcharts for explaining positioning processing steps;

FIG. 7 is a diagram for explaining image accumulation steps;

FIG. 8 is a diagram for explaining a method for calculating the movement amount of a FOV;

FIG. 9 is a diagram for explaining types of a trajectory of FOV movement;

FIG. 10 is a diagram for explaining an example of a method for calculating a distance between FOV's;

FIG. 11 is a diagram for explaining an example in which FOV's are partly overlapped;

FIG. 12 is a diagram for explaining a method for resolving a case where FOV's are partly overlapped;

FIG. 13 is a diagram for explaining a method for setting FOV's for accumulation when a reference FOV is set in a pattern arranged at an edge of an identical/similar pattern group;

FIG. 14 is a diagram for explaining a method for setting FOV's for accumulation on an identical/similar pattern group;

FIG. 15 is a diagram for explaining steps of acquiring a reference FOV and FOV's for accumulation;

FIG. 16 is a diagram for explaining a schematic of a measurement system including a plurality of measurement devices;

FIG. 17 is a diagram of a schematic construction of a scanning electron microscope;

FIG. 18 is a diagram for explaining an example of a GUI for image acquisition condition setting;

FIG. 19 is a flowchart for explaining an example of image acquisition steps;

FIG. 20 is a flowchart showing an example of a process of creating a recipe for a scanning electron microscope;

FIG. 21 is a diagram for explaining an example of a GUI screen for recipe setting; and

FIG. 22 is a flowchart showing a processing process of pattern measurement.

### DESCRIPTION OF EMBODIMENTS

In recent years, with higher integration and refinement of a semiconductor device a technique for inspecting a fine pattern correctly at high speeds has been becoming important. Because of refinement of a pattern and performance limitation of hardware, however, a processing is executed through such a sequence that positioning is conducted using an image processing technique at magnifications of several levels and an image focused eventually at a magnification for measurement at a correct position is obtained to carry out length measurement at the moment.

For example, a characteristic pattern (reference image) and its position are memorized at magnifications of several levels and at positions, pattern matching is performed with an actual inspection image to detect its position automatically, and a position of a fine pattern to be measured eventually is detected.

Further, in order to prevent the image quality from being degraded due to a change in the height of a wafer or the like, a processing of focusing a pattern automatically or manually is also performed. Those pieces of information of the reference image, measurement conditions (for example, information as to measurement of a line width, measurement of a hole diameter, or the like), and focusing information (information as to how much distant from a pattern detection position, how much the magnification, in what method the focusing is executed, and the like) are saved as a set.

A sequence of conducting positioning/length measurement in respective steps is explained hereunder. In the following explanation, incidentally, a description is given by way of example of a scanning electron microscope (SEM) being one of charged particle beam devices but it is not limited thereto and, for example, application to an ion-beam device in which an ion beam of helium ions, liquid metal ions, or the like is irradiated on a sample is also possible.

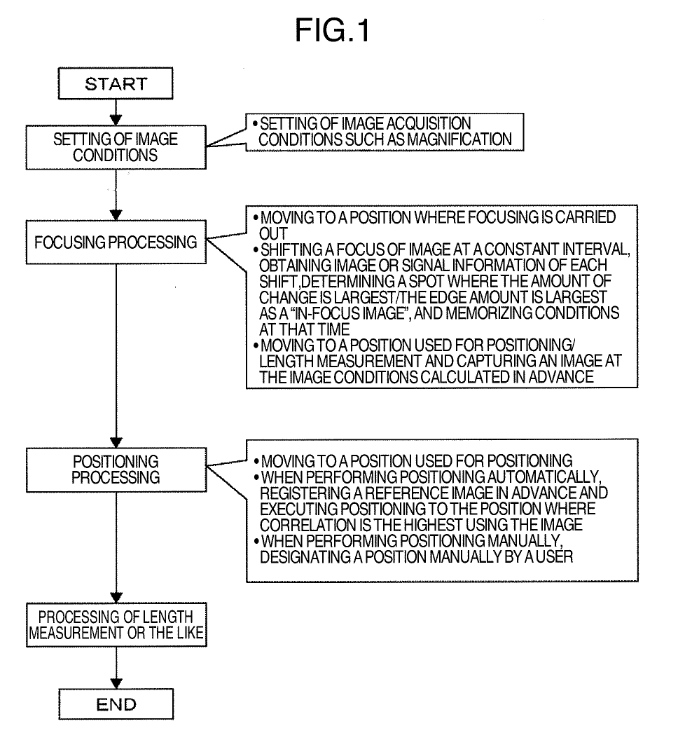

FIG. 1 is a flowchart for explaining a process from setting of conditions of a device to measurement. First, measurement conditions and image (or profile) acquisition conditions are set. For example, magnifications, acquisition positions (coordinates), and the number of measurement points for measurement images, conditions for conducting focusing and positioning, and the like are set herein. Such conditions are registered as a recipe to be described later ((1) setting of image conditions).

Next, based on the conditions set in the above step, a field of view of SEM is moved to a position where focusing is conducted and focusing is carried out at the position. As an example of a focusing processing, the focal point is changed at a constant interval by changing an excitation current or an applied voltage of an objective lens or by changing an applied voltage to a sample, a focal point evaluation value such as the degree of sharpness of an image is determined based on the signal (image, for instance) obtained at a time, an image for which the value is maximized is judged as an in-focus image, and the current or the voltages applied at that time are set as control values for the lens or the like ((2) focusing processing).

Subsequently, at the predetermined measurement or inspection conditions, a positioning processing for properly conducting measurement or inspection is carried out. Here, based on design data or the like of a semiconductor device or an SEM image or the like an image is formed in advance and positioning with that image (for example, template matching) is carried out. As a general method, a reference image or design information is set (registered) in advance, its correlation to an actual image is calculated, and a position where the correlation value is maximized is set as a “position to be detected” with which the position is aligned ((3) positioning processing).

Then, if it is a sequence for eventually performing length measurement or other inspection, length measurement, other inspection, or an imaging processing for image saving is conducted ((4) processing of length measurement or the like). Here, for simplicity of explanation, a term “image” is used but it corresponds to a processing for acquiring signal information for execution of respective processings and is not necessarily image information.

Generally, by taking account of influences due to electron beam irradiation on a measurement pattern, the processing of (2) is preferably executed at a position different from those for the processings of (3) and (4). Also, there is an occasion when the position at which the processing (3) is executed may be off from an expected spot due to the position accuracy of the device or the precision of pattern detection at a low magnification executed as a pre-process of the processing (3), and in that event the position may be corrected and the image acquisition process may be executed again in order to execute the processing (4) with high accuracy.

Here, in focusing or acquisition of images (signals) at the measurement/inspection positions, by scanning the electron beam plural times within the same FOV (one electron beam irradiation within the FOV will hereinafter be called “scan”) and superposing signals of, for example, four frames or eight frames resulting from carrying out electron beam irradiation at the same FOV, an image (or signal) at the position is determined. By executing the scan plural times and forming an image, noises of the image can be mitigated to permit stable measurement/inspection to be conducted.

On the other hand, scanning plural times on a sample may cause phenomena as below. In the example of FIG. 1, images or waveform signals (sometimes called images or the like hereinafter) are acquired plural times for optical condition adjustment such as focus adjustment, positioning, and measurement. At that time, by irradiating the electron beam continuously at the same position, a phenomenon called shrink in which a pattern is damaged and shrunk or a phenomenon called contamination in which impurities are attached to the pattern so that the pattern appears to be thicker may occur.

Through these phenomena, there are possibilities such that the results of measurement are inaccurate or a shape of the pattern per se used for measurement is changed thereby affecting the eventual performance or the like of an object to be measured.

Although influences and a frequency of the phenomena such as shrink or contamination as above change with raw materials of a pattern to be measured, the amount of irradiated electrons, an irradiation time of the electron beam, and the like, the aforementioned phenomena become conspicuous in any of the cases in general as the amount of irradiated electrons becomes larger and the irradiation time becomes longer, with the result that the shape of the pattern per se is changed and, therefore, the influences are needed to be minimized.

For patterns such that the patterns to be used in a processing are part of a plurality of similar patterns existing within a certain range as objects, in order to suppress occurrence of such phenomena as shrink and contamination, a method of acquiring an image or the like while moving the position in the respective steps of (2) focusing processing, (3) positioning processing, and (4) processing of length measurement or the like among the processing shown in FIG. 1 is described.

Since an excessive irradiation of the electron beam to a given spot can be suppressed by acquiring images or the like while moving the position, occurrence of shrink or contamination can be suppressed. In the step of acquiring the images or the like described above, it is preferable that conditions such as whether images or the like are obtained at the same position, whether images or the like are acquired while moving the position, or the like, or conditions such as a distance, the number of times, and a time interval of position movements when image acquisition is carried out while moving the position can be arbitrarily set. These conditions may be set manually but, by memorizing together when sequence conditions are registered, the process can be executed automatically.

Upon executing the acquisition processing for images or the like as exemplified in FIG. 1, an image is first acquired at a magnification of about 100 to 500 times using an optical microscope or a metallurgical microscope in consideration of the position accuracy of the device and the manufacturing accuracy of an observation object (such as differences between positions/shapes in design data and positions/profiles of actually formed patterns) and, thereafter, the predetermined processing is executed.

Since the positioning or the like using an optical microscope is conducted to improve the accuracy of the processing in the measurement/inspection step described later, the present processing may be omitted in case where, for example, the eventual measurement positions are formed by a repetitive pattern over a wide range and measurement of any spot in the range is satisfactory (namely, too high a positioning accuracy is not needed).

Subsequently, an image is acquired at a magnification of about 1000 to 20000 times. Using the image or the like acquired at such a magnification, processings of optical condition adjustment such as focusing or astigmatism correction and/or positioning are executed. These processings may be carried out as necessary and need not be executed necessarily.

After going through the device condition adjustment and positioning processings described above, the measurement/inspection processing is carried out.

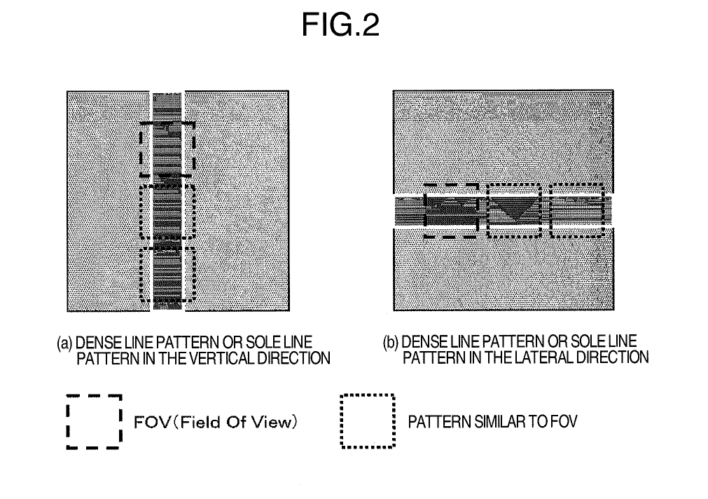

A signal processing method (a method for forming images or the like) to be explained in the present embodiment is applicable when forming images at various magnifications in the respective processes exemplified in FIG. 1. FIG. 2 is a diagram for explaining examples of forming an accumulated image using signals obtained based on electron beam scans at a plurality of spots in a line pattern. Part (a) of FIG. 2 is a diagram for explaining an example of a line pattern extending in the vertical direction (the Y direction). In this example, image signals obtained by scanning the electron beam at a reference FOV and image signals obtained by scanning the electron beam at a different position with the same line pattern as the reference FOV are accumulated. The pattern within the reference FOV and the pattern at the different position are those of the same shape in design data and they are considered as being very similar in shape even after going through the production step and an image being substantially the same as an image for which signals obtained through scanning conducted plural times within the reference FOV are accumulated can be formed.

Further, since the amount of irradiation of electron beam per unit area can be controlled without changing a magnification in one of the X direction (the lateral direction) and the Y direction with respect to the magnification in the other direction, an image can be formed at the constant vertical and lateral magnifications while suppressing occurrence of the shrink or the like. Incidentally, when executing accumulation of image signals at different positions, it is preferable that positioning between respective image signals be conducted and, then, the images be accumulated. Part (b) of FIG. 2 is a diagram for explaining an example of a line pattern extending in the lateral direction. The aforementioned image accumulation method accompanied by moving the FOV can also be applicable to such a pattern and the FOV's are set at positions different from that of the reference FOV along the line pattern.

In order to use the aforementioned image accumulation method for measurement, inspection, positioning, or optical condition adjustment, information of positions of the respective FOV's (or relative positions to the reference FOV) are registered in advance and, based on the registered information, the SEM is controlled by a control unit such that the FOV movement can be carried out. It is to be noted that in case the aforementioned image accumulation method is applied to the positioning processing, a reference image (template) therefor is registered in advance.

As for the patterns exemplified in FIG. 2, the pattern is considered to exist repetitively in the vertical or lateral direction and, hence, the interval may be considered as being equivalent to the FOV. Although the interval can be set arbitrarily, with the FOV's overlapped with each other, the amount of irradiation of the electron beam increases at the overlapped portion and, accordingly, the distance between the center position of a FOV and that of the adjacent FOV is desired to be set to a width or a height of the FOV or more.

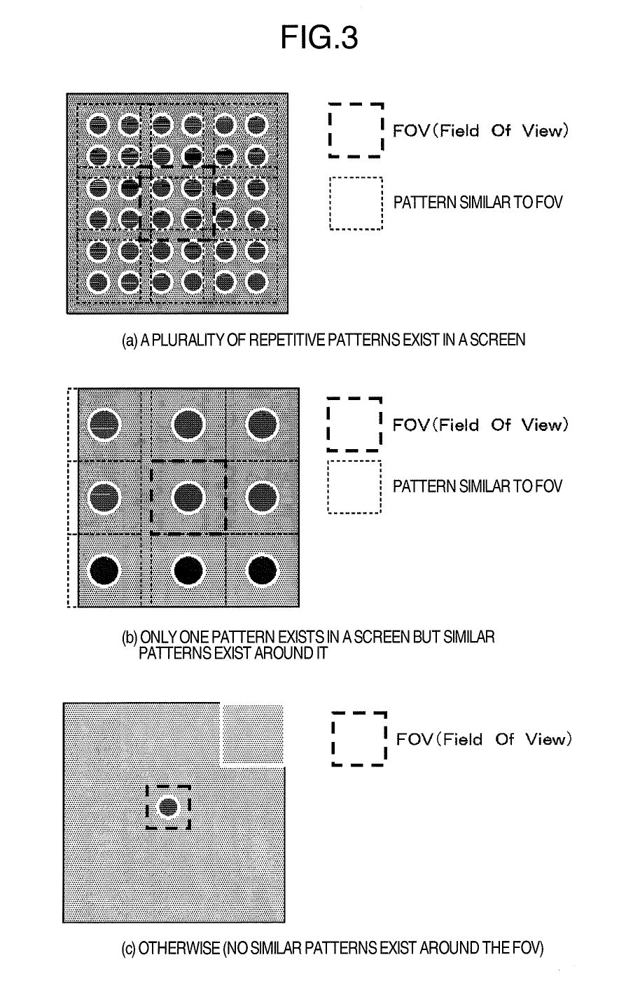

FIG. 3 is a diagram for explaining an example in which a repetitive pattern exists continuously in the neighborhood (within a low-magnification image). In the case of a pattern exemplified in Part (a) of FIG. 3, unlike a line pattern candidates for FOV's for accumulation exist in both the X direction and the Y direction and, hence, in this example, image signals are acquired in 3×3 FOV's and image signals of the nine sets are accumulated. It will be appreciated that in Part (a) of FIG. 3 the adjacent FOV's overlap in part; they may overlap in part in accordance with a size of a pattern to be accommodated within one FOV and an tolerable amount of shrink or the like. Especially, since the amount of irradiation on one FOV can be decreased as the number of FOV's increases, partial overlap of the FOV can be made permissible as giving preference to the degree of freedom of selecting the size of FOV.

In order that in respect of the pattern as shown in Part (a) of FIG. 3 the FOV's are to be prevented from being overlapped with each other, a distance between the FOV's is calculated by a method in which images are acquired while moving the position by an amount corresponding to a FOV or by an arbitrary amount in advance and an amount of a positional movement in relation to the image before moving is measured or the like and the result of calculation is registered as a movement amount during FOV acquisition. For example, through a method in which a FOV at an initial position is set and design data or a distance between patterns is measured manually by lowering magnification, the pattern distance is calculated and set.

Even when the image signal acquisition position is set not to cause FOV's to overlap with each other, there is a possibility that it is off from the expected position on account of lack of positional accuracy due to the performance of the hardware. In such an event, since there is a possibility that a problem to be described later arises by irradiating the electron beam plural times to only a part in the course of moving the position and irradiating the electron beam, the interval may preferable be set as being slightly larger than the FOV. A rule of thumb in setting to a herein is a value equal to or greater than the positioning accuracy of the device.

Further, in the case of a pattern as shown in Part (b) of FIG. 3, the interval can be calculated by acquiring it from design data or by acquiring an image while lowering the magnification. FIG. 10 exemplifies a method for determining a distance (interval) between respective FOV's which are used for obtaining images subject to accumulation. For example, in a processing of registering a reference image used for the positioning processing, there is a case where a single unique pattern exists in a FOV at the image acquisition conditions at the time of measurement/inspection (for example, in Part (a) of FIG. 10). In case identical or similar patterns exist around this pattern, the size of a FOV is increased (by lowering the magnification of SEM) to make the neighboring patterns to be included in the FOV (for example, in Part (b) of FIG. 10). After setting the size of a FOV large in this manner, the interval between the FOV representing a reference and the FOV including neighboring patterns is calculated and registered (for example, Part (c) of FIG. 10). For the interval between the FOV's, the distance between centers of hole patterns, for example, may be obtained from the size of the FOV and the number of pixels between the hole centers or, if design data can be referenced, the distance between them may be determined by referencing the design data (for example, GDS data).

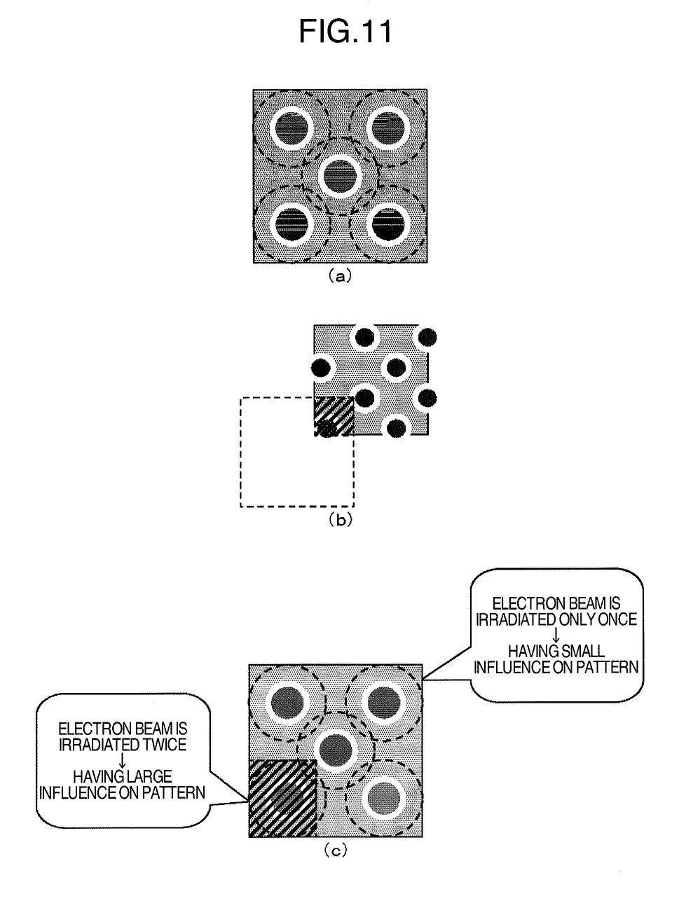

Presumably, when the electron beam is irradiated while the position is moved plural times, however, there would occur an event that with positions overlapped partly depending on the positioning accuracy of the device the electron beam is irradiated plural times. Such overlapping is explained with reference to FIG. 11.

Part (a) of FIG. 11 illustrates an example where five hole patterns are included in a FOV. In this example, this FOV is acquired to measure five hole patterns surrounded by dotted lines. Here, there is a possibility that adjoining FOV's overlap on account of decrease in positioning accuracy of the SEM or of the distance between FOV's (a distance of moving a FOV) set smaller than a FOV. For example, when the a distance of moving a FOV is set smaller than the FOV, the FOV at the measuring position and the FOV at the position after moving will partly overlap as indicated by a hatched portion shown in Part (b) of FIG. 11. This overlapped portion undergoes electron beam irradiation twice through image acquisition at the measuring position and image acquisition at the position after moving. Considering conditions of electron beam irradiation at the measuring position, only a lower left spot (the hatched portion in Part (c) of FIG. 11) out of five measurement points within the FOV is scanned repeatedly. At the other four measurement points within the FOV the electron beam irradiation is only once, giving rise to different electron beam irradiation conditions at the measuring positions. In case the sample is suffered from occurrence of the phenomena of shrink, contamination, or the like due to electron beam irradiation, it leads to unstableness of measurement results and, hence, it is desired to make the amount of electron beam irradiation to the measurement object pattern be constant.

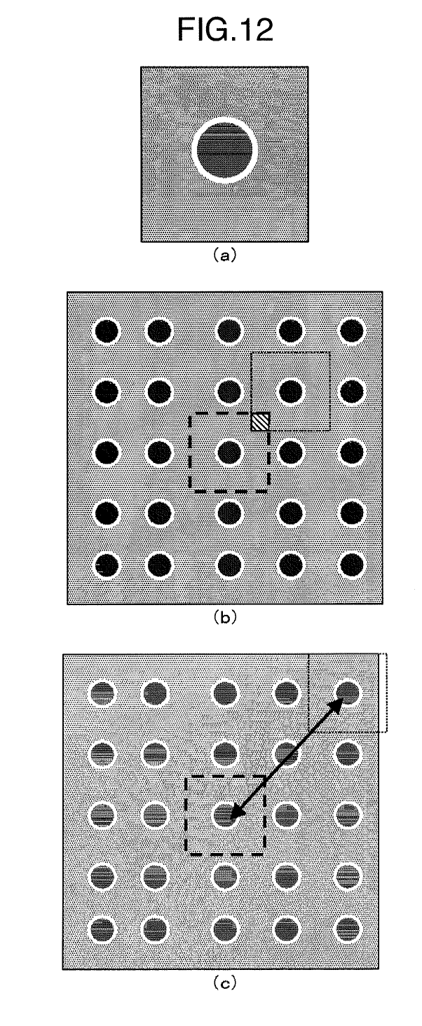

A method for determining the amount of moving a FOV necessary for the electron beam irradiation amount to be uniform at a plurality of measurement points is explained with reference to FIG. 12. When the interval between patterns to be calculated is smaller than the FOV (Field Of View), the electron beam is irradiated plural times with a partial area rendered overlapped at the time of acquiring images while displacing images by the interval and there is a possibility that the phenomena such as shrink and contamination attachment would be induced. Especially, in the case of an example of Part (b) of FIG. 12, since the electron beam is scanned plural times on a hatched portion, possibility of occurrence of shrink or the like would become higher. Accordingly, when another FOV for accumulation is set around such a reference FOV as exemplified in Part (a) of FIG. 12, the interval between the two is set preferably to at least the FOV or a value equal or greater. For example, by setting the interval between the reference FOV and another FOV for accumulation to about 1.5 times the FOV and performing the positioning in the range of ½ of the FOV in the neighborhood, overlapping of FOV's can be prevented. In reality, however, it is preferable to set a spacing of about an amount of 1.5 times+α of the FOV as exemplified in Part (c) of FIG. 12 by taking account of the movement accuracy of the device when moving to the respective positions. For example, in Part (c) of FIG. 12, the interval between FOV's is set to an arbitrary value which is 1.5 to 2.0 times a FOV.

In the case of a pattern in which the identical or similar patterns are arranged at an equal interval as exemplified in FIG. 12, when a FOV nearest to the reference FOV is selected as a FOV for accumulation, there is a possibility of the two FOV's overlapping with each other and, therefore, along with the position of the FOV for accumulation being set by skipping one pattern, the interval of 1.5 times or more and 2.0 times or less may preferably be set as a FOV moving range by considering that the pattern search is carried out within the range of ½ of a FOV. The overlapped scan may possibly take place even for the line pattern exemplified in FIG. 2 and the aforementioned method for determining the FOV for accumulation can also be applicable to the line pattern.

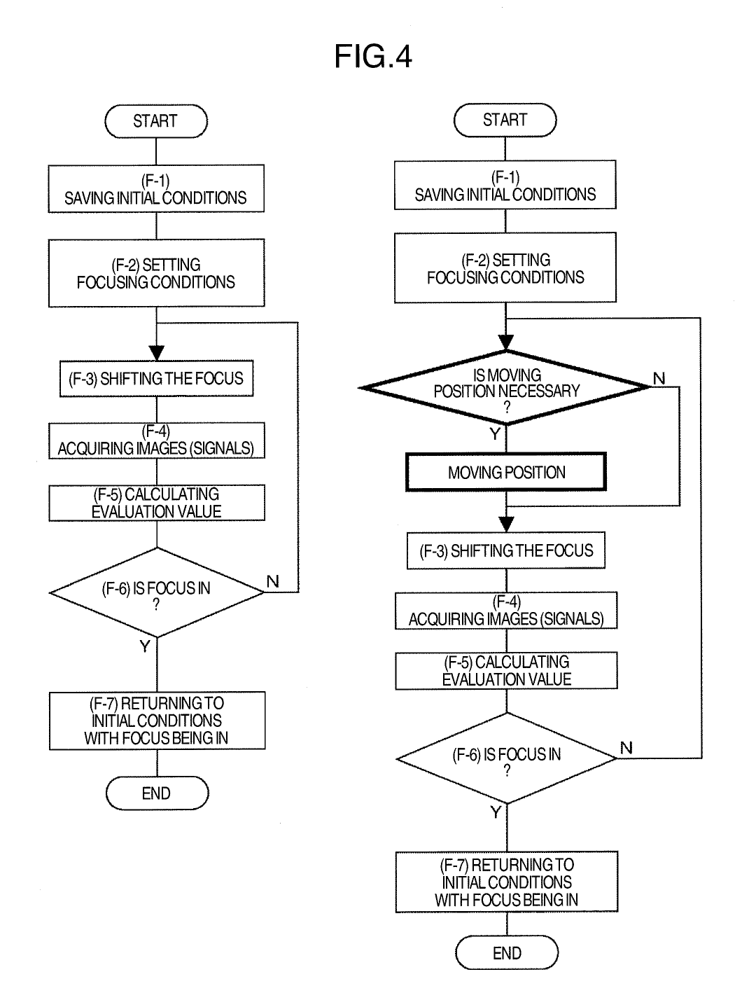

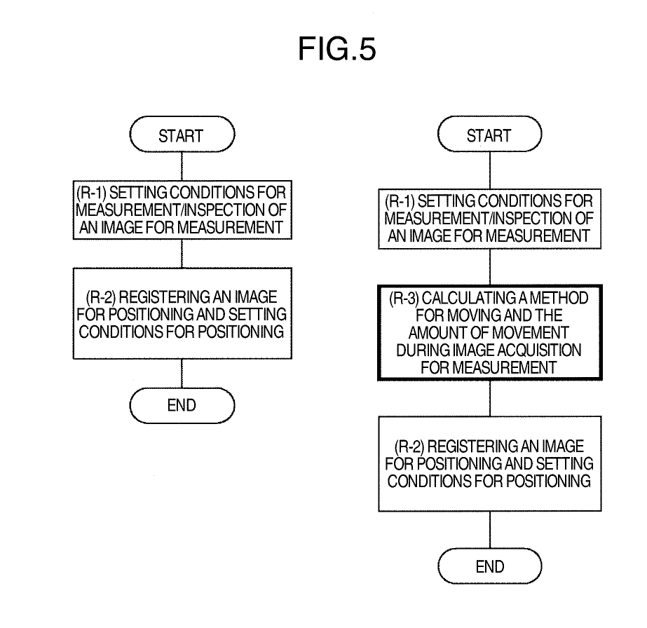

Information of the pattern shape and the interval between similar patterns as described above is memorized together with a reference image and measurement conditions when either the focusing processing exemplified in FIG. 4 or the registering processing of conditions for positioning as shown in FIG. 5 is executed and is rendered usable in the course of execution of manual or automatic measurement. In conducting actual measurement, processings as below would, for example, be executed.

In executing the processings exemplified in FIG. 1, since the reference image, its existing interval, the focusing processing, and its interval are memorized, the processing of focus adjustment, positioning, measurement or the like is conducted using the information. In order to avoid repetitive execution of position correction and a scan after, for example, positioning (namely, in case where an image acquired for positioning is used as is for measurement) when conducting the processings exemplified in FIG. 1 at high magnifications, the number of sheets of scans is set again before an image for positioning is acquired, images are acquired while moving the position, and an image for measurement is formed by accumulating those images. In addition, by combining with a processing such as conducting a positioning processing at a position different from that for the measurement/inspection processing, an image (signal) for measurement/inspection can be acquired with high positioning accuracy while minimizing the amount of electron beam irradiation at the measurement/inspection position.

Generally, for acquisition of an image, an area of a FOV (Field Of View), for example, is scanned plural times and the image is generated by accumulating these pieces of information. By rendering information obtained through one scan of the FOV as one frame image and by accumulating information of a plurality of frames (for example, four, eight, or sixteen) to reduce the amount of noise, an image used for observation and measurement is generated.

In the present scheme, when an image of, for example, eight frames is desired to be obtained eventually, moving to similar patterns of eight positions, for example, in the neighborhood of the measurement position and acquiring images of one frame each or acquiring images of two frames each at four positions to be accumulated so that an image for measurement is produced.

As a method for acquiring images, for patterns as shown in Part (a) and Part (b) of FIG. 2, for example, images may be acquired with moving up and down and left and right at a certain interval. For patterns as shown in Part (a) and Part (b) of FIG. 3, images are acquired while moving a position, for example, centered around the measurement position in clockwise or counterclockwise, moving the position stops at the time that the total number of frames of acquired images becomes equal to the total number of sheets of frames of images desired to be acquired, and the images are accumulated. In moving the position, the interval for repetition of images acquired at the time of registration of the reference image is used to make the area of overlap of images as large as possible. Further, when, in the course of acquiring images while moving the position a pattern is absent at a position when the position is moved since the initial position is off, an image at the position is not used and either by moving to a different position or by increasing the number of sheets of frames at respective spots the total number of sheets of frames is made to become a desired number of frames.

According to the method as described above, the sequence up to measurement can be executed while mitigating the amount of electron beam irradiation in the respective areas mainly in a repetitive pattern. A series of these sequences are memorized and the measurement/inspection is conducted, for example, by consecutively executing the aforementioned processings at a plurality of positions within a wafer. An example to which the present embodiment is applied when the processings exemplified in FIG. 1 are executed at high magnifications is described hereinafter. It is also applicable to the focusing and positioning processings at plural magnifications, which correspond to the preprocessing of the present high magnification measurement processings.

First, in order to set measurement conditions, movement to a pattern to be measured is conducted and measurement conditions (the number of sheets of frames, a measurement method, and other measurement parameters) are set. Thereafter, a reference image used for positioning and its position, conditions for detection of a pattern for positioning, and the like are set. It is presumed that, in this case, a measurement image and an image for positioning are parts of a repetitive pattern, respectively, and similar patterns exist around them, respectively.

Patterns to possibly be measurement objects are considered to be of five types below. Firstly, it is a line pattern in the vertical direction (including a dense line pattern or a sole line pattern in the vertical direction) as exemplified in Part (a) of FIG. 2; secondly, it is a line pattern in the lateral direction (including a dense line pattern or a sole line pattern in the lateral direction) as exemplified in Part (b) of FIG. 2; thirdly, it is a plurality of repetitive patterns (for example, hole patterns) existing within one FOV as exemplified in Part (a) of FIG. 3; fourthly, it is a pattern solely present within a FOV but accompanied by similar patterns around it as exemplified in Part (b) of FIG. 3; and then, a pattern for which identical or similar patterns do not exist around the FOV as exemplified in Part (c) of FIG. 3.

The present embodiment is principally effective for application to the first to fourth patterns. As to which of the above category an intended pattern belongs to it may preferably be obtained as pre-information through any of the following methods. The method for acquiring the pre-information may be executed in advance of the execution of the processings in FIG. 1 or may be executed in the respective processings (1) to (4) in FIG. 1. The following may be considered as a method for setting. First, a user makes a choice in advance; a decision is otherwise made from information of design data automatically or manually by the user; alternatively, a decision is made through a known pattern decision method; and so on.

A method for setting conditions for measurement and the like after the kind of pattern is specified based on the pattern type decision method as above is described below.

(1) Determination of the Number of Times of FOV Movement and Conditions Therefor

First, the number of times of moving the FOV and the number of frame sheets of images at respective spots are set. For example, when the number of sheets of image frames to be obtained eventually for measurement/inspection is eight, setting such as (1 frame)×(8 spots), (2 frames)×(4 spots), or the like is carried out. Furthermore, the number of frame sheets at each of the positions is changed as necessary. In this case, it is possible to acquire images of, for example, 2, 2, 1, 1, and 2 frames at five spots, respectively; but in this example, the number of frame sheets is made identical at the respective spots for simplicity of explanation.

In addition, conditions of magnification or the like are set. For example, images are acquired at a ½ magnification and then an enlargement processing may be executed through image processing to obtain images at a measurement/inspection magnification; but for simplicity, the magnification is set as identical. Besides, the moving method and the moving distance in each of the shapes need to be memorized. Concerning the moving method and the moving distance, they can be selected in accordance with the pattern shapes, respectively.

Next, examples of methods for determining the moving method and the moving distance for each type of patterns are described. Attention is herein made to the fact that it is important to operate such that the FOV (Field Of View) before moving and that after moving basically do not overlap with each other. In this point, moving by an amount of a FOV at least is necessary but actually, since it also depends on the position movement accuracy of the device, movement is set to be at intervals of FOV+α. When, as long as an object pattern is present within a screen, being off in its position to some extent does not cause a problem for performance, as in the case of the focusing processing, movement may simply be done by FOV+α.

(2-1) In the Case of First and Second Patterns

Here, the moving distances for moving to the respective positions are set. This setting is memorized in association with the patterns with, for example, a GUI (Graphical User Interface). It may be moved at the aforementioned interval either up or down in the vertical direction in the case of the pattern exemplified in Part (a) of FIG. 2 or either left or right in the case of the pattern exemplified in Part (b) of FIG. 2 to acquire images of a desired number of sheets. In case it is a dense pattern and similar patterns are present around it, however, a method to be described later may be applied.

(2-2) In the Case of the Third Pattern

Like the first and second patterns, the number of times of movement and the number of frames at respective spots are first set and then it is moved clockwise or counterclockwise centered around the start position to obtain images.

(2-3) In the Case of the Fourth Pattern

An image is acquired with the magnification lowered by, for example, ⅓, a decision is made as to whether similar patterns are present in the neighborhood, and, if present, distances to the respective positions are calculated in advance.

Through the procedures exemplified above, registration of conditions for measurement at a high magnification and conditions for a reference image used for positioning ends.

Next, as for the focusing processing, the outline of automatic focusing (auto-focus) and specific processing steps taken when acquisition of images concomitant with FOV movement is conducted with auto-focus is described using FIG. 4. FIG. 4 shows flowcharts for explaining examples of the auto-focus processing steps with the left drawing in FIG. 4 being for explaining auto-focus steps unaccompanied by the FOV movement and the right drawing in FIG. 4 being for explaining auto-focus steps accompanied by the FOV movement. First, (F-1) to (F-7) in common to both the auto-focus steps are described.

(F-1) Saving of Initial Conditions

Focus position conditions (an excitation current and an application voltage of the objective lens, and a retarding voltage) at the time of the initiation are saved. Since the automatic focusing is expected to be executed by, for example, limiting the number of frames of images or by using a location, a magnification, and the like which are different from those for positioning, they are memorized at the beginning of the processing in order that they can be restored to original conditions when the processing ends.

(F-2) Setting of Focusing Conditions

For the focusing, conditions of a fixed number of frame sheets (in general, images of a smaller number of frame sheets than that for the positioning or measurement processing are expected to be used) and of a magnification at which the auto-focusing is executed are set as described later. Since the execution after setting a specific rotation or the like to an object pattern may be possible, conditions therefor are permitted to be set.

Hereinafter, the processings of from (F-3) to (F-6) are repeated until in-focus is attained.

(F-3) Shifting Focus

The focus is shifted within a certain range.

(F-4) Acquisition of Images (Signals)

Images or signals are acquired while the focus is shifted in (F-3).

(F-5) Calculating Evaluation Value

An evaluation value is calculated using the image (signal) acquired in (F-4). As a method for calculating the evaluation value, a method may be considered in which an edge amount based on a differential processing is calculated to be an evaluation value.

(F-6) Making Decision as to Whether Focus is in

By using the evaluation value calculated in (F-5), it is decided whether the focus is in. In the case of the in-focus status, the processing ends; when out-of-focus is determined, the flow returns to the processing of (F-3).

(F-7) Returning to Initial Conditions with Focus Being in

When the in-focus status can be determined in the (F-6) processing, conditions are returned to the initial conditions (such as the number of frame sheets of images, magnification, and rotation) which are saved in F-1 while the focus is still in.

Next, (F-8) and (F-9) specific to the auto-focus based on image acquisition accompanied by the FOV movement are described.

(F-8) Deciding Whether Moving Position is Necessary or Not

From the aforementioned limitations imposed on the number of times of position movement and the amount (or the number of times) of electron beam irradiation at the same spot or the like, it is decided whether the position needs to be moved or not. If moving position is needed, a processing of (F-9) is carried out.

(F-9) Moving the FOV Position

The position is moved in accordance with the aforementioned pattern shape or the like. Concerning the moving method, the moving distance, and the like, operation is conducted through the methods which are registered in advance in accordance with the pattern shape and the like as described previously.

In case the evaluation value calculation in (F-5) is essentially based on the edge amount by differential calculation or the like, an offset of the position to some extent is considered to cause no problem on the evaluation value calculation as long as a pattern executed for focusing is present within the FOV; but, if adjustment of an accurate position is necessary, a reference image for positioning, for example, is acquired in advance and positioning may be conducted after the position is moved in (F-9).

Further, with regard to the processing of shifting the focus in (F-3), it is presumed that an image becomes unstable by shifting the focus, for example, immediately after moving the position depending on characteristics of the device, the method for shifting the focus, or the like and, therefore, the processings of (F-8) and (F-9) may be executed between (F-4) and (F-5) or (F-5) and (F-6), for instance.

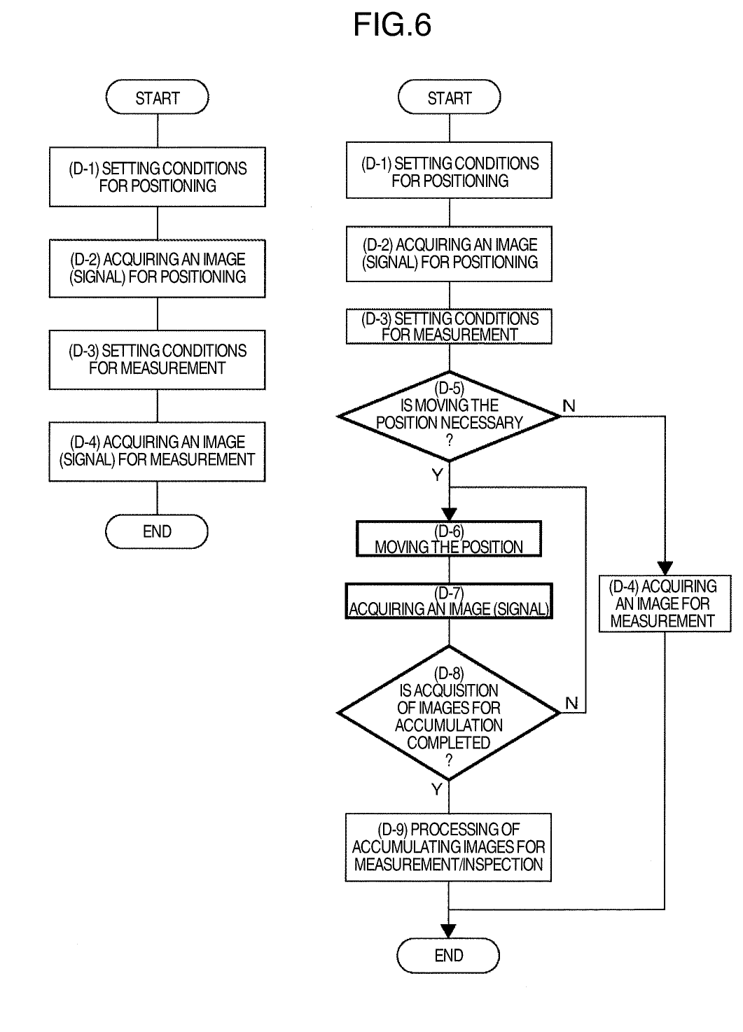

Next, in terms of the positioning processing, the outline of the positioning processing and specific processing steps when image acquisition accompanied by FOV movement is conducted in the positioning processing are described using FIG. 5 and FIG. 6. Incidentally, images acquired in this step can also be applied to the measurement/inspection processing.

In the positioning processing, an image (signal) used eventually for the measurement/inspection processing is acquired and in case an image is acquired again in the measurement/inspection processing, it is also applicable to the measurement/inspection processing.

FIG. 5 shows flowcharts for explaining a positioning condition setting step with the left drawing in FIG. 5 being for explaining a positioning condition setting step unaccompanied by the FOV movement and with the right drawing in FIG. 5 being for explaining a positioning condition setting step accompanied by the FOV movement. First, (R-1) to (R-2) in common to both the auto-focus steps are described.

(R-1) Setting Conditions for Measurement/Inspection of an Image (Signal) for Measurement

It is moved to a pattern to be measured actually and conditions for an image to be measured (a magnification, the number of frame sheets, measurement conditions, and the like) are set.

(R-2) Registering an Image (Signal) for Positioning and Setting Conditions for Positioning

It is moved to a position for positioning and the conditions are registered.

The magnification and the number of frames of an image (signal) for positioning, a positional relation to the measurement position registered in R-1, the method for positioning, and the like are set.

If the influence the electron beam irradiation has upon the measurement object and a certain degree of positional accuracy during measurement are necessary, the positions used in R-1 and R-2 are preferably set to different positions so that they do not overlap with each other.

Next, a positioning condition setting step (R-3) based on image acquisition accompanied by moving the FOV is described.

Processings of (R-1) and (R-2) in the right drawing of FIG. 5 are identical to the processings described with reference to the left drawing of FIG. 5; but in a flowchart in the right drawing of FIG. 5, after the measurement image is acquired in (R-1) calculations of a method for moving the FOV and an amount of movement are conducted in (R-3).

(R-3) Calculating a Method for Moving and the Amount of Movement During Image Acquisition for Measurement

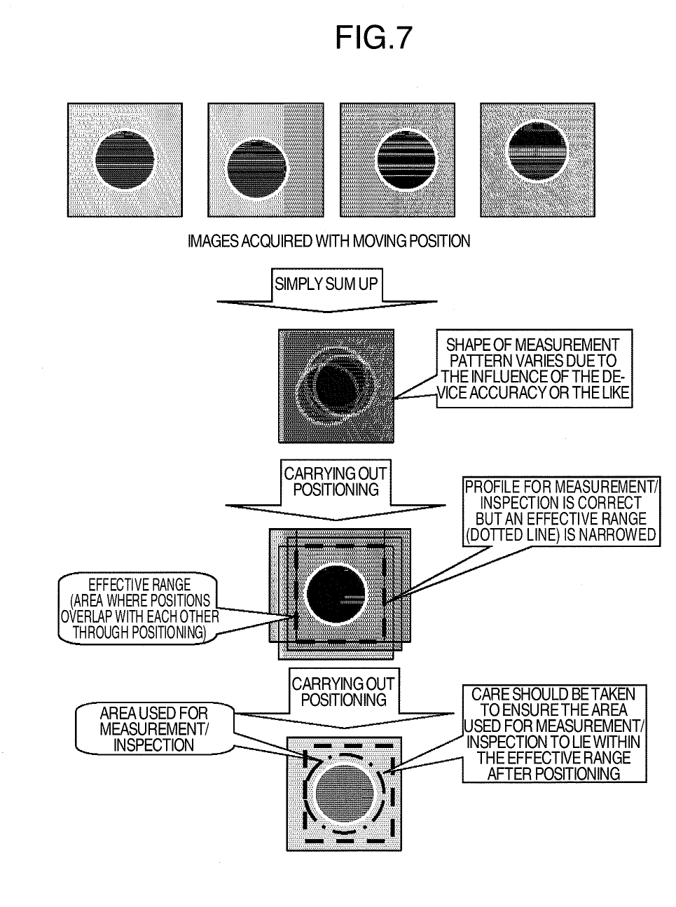

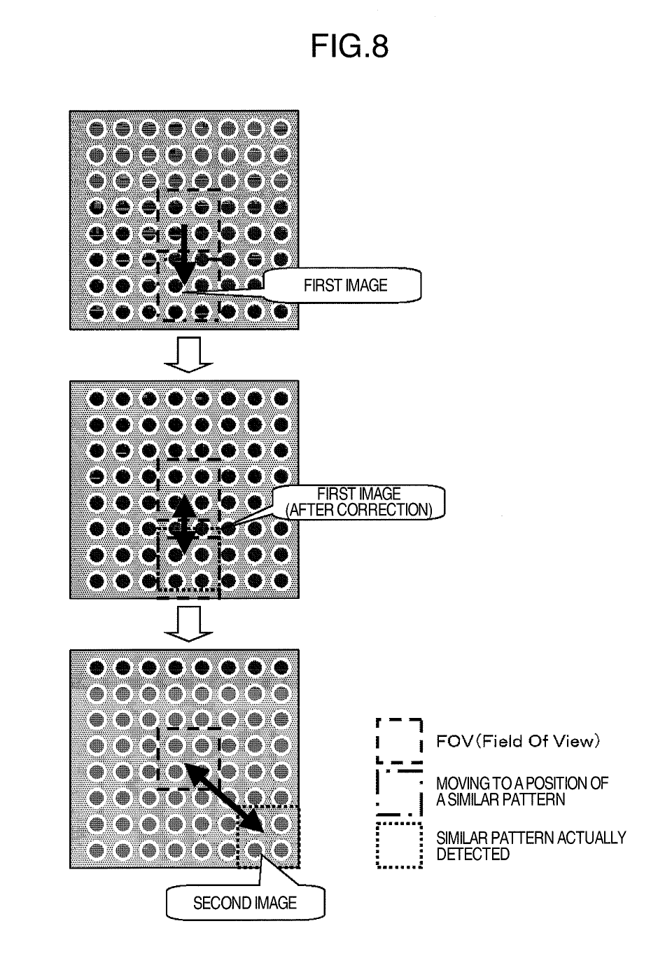

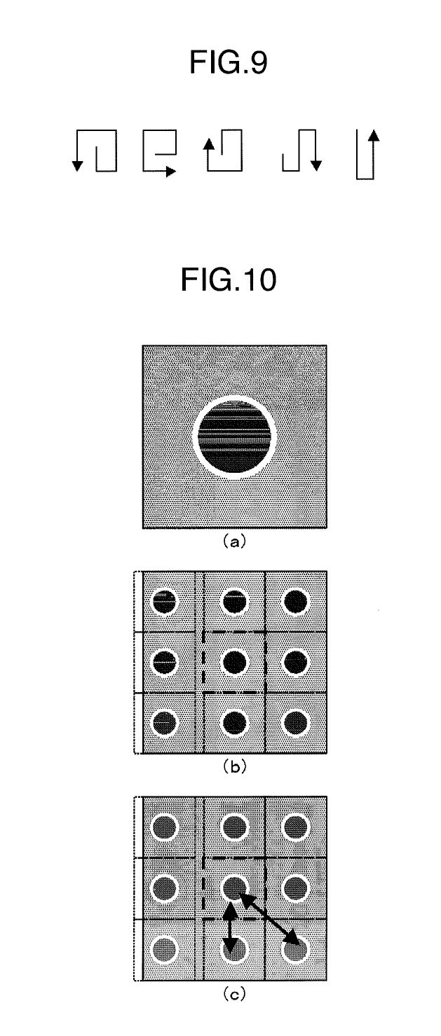

When conditions for measurement are obtained, a method for moving and the amount of movement are calculated from information of a pattern shape of an image for measurement or the like. For example, in case a pattern of a measurement object is constituted by a repetitive pattern as exemplified in Part (a) of FIG. 3, the amount of movement is calculated according to methods exemplified in FIG. 7 and FIG. 8. As an example of the moving method in this case, moving methods of clockwise or counterclockwise centered at the start point, up and down, or the like as exemplified in FIG. 9 can be considered.

Illustrated in FIG. 8 is an example in which it moves down once from a start point and subsequently moves counterclockwise. In the figure, an area indicated by dotted lines at the center is rendered as the start point (a FOV including an eventual measurement/inspection point) and the FOV is moved by (Δx, Δy) downward from the start point to a position indicated by dot and dash lines. The moving distance of this time may be equivalent to the FOV or may be defined in advance. An image at this position is set as a first image.

The image (signal) at the start point is memorized as a reference image for positioning and is subjected to positioning with the first image to calculate an amount of an offset. By taking the calculated amount of a position offset into account, an amount of the offset between the reference image and the first image (after correction) is memorized as (Δx1′, Δy1′). Thereafter, it is moved to the next position (in this example, to the right) to acquire a second image and an amount of the offset from the reference image is memorized as (Δx2′, Δy2′).

The above processing is executed by the number of times of position movement (the number of frames necessary for accumulation) and the amounts of position offsets between the reference image and the respective positions are memorized. These pieces of information are memorized together as pieces of positioning information, respectively. Further, to avoid overlap between FOV's, each of (Δxn′, Δyn′) need be set as being larger than the width and the height of a FOV.

FIG. 6 shows flowcharts for explaining examples of the positioning step, with the left drawing of FIG. 6 explaining the positioning step unaccompanied by FOV movement and the right drawing of FIG. 6 explaining the positioning step accompanied by FOV movement. First, steps (D-1) to (D-4) in common to both the positioning processings are described.

(D-1) Setting of Conditions for Positioning

Setting to the conditions for positioning (information of a position, a reference image, a magnification, a rotation of an image, and the like) registered in the processing for registering the conditions for positioning is carried out.

(D-2) Acquiring an Image (Signal) for Positioning

An image used for positioning is acquired.

(D-3) Setting Conditions for Measurement

Conditions for acquiring an image for measurement (a position, a magnification, a rotation of an image, and measurement conditions) and the like are set.

(D-4) Acquiring an Image (Signal) for Measurement

An image (signal) for measurement is acquired. When the (D-1) conditions for positioning are identical to the (D-3) conditions for measurement, the processings of (D-3) and (D-4) can be omitted. Also, even if the conditions of (D-1) and (D-3) are the same, the processing (D-4) may occasionally be conducted after the position is corrected using the information of the position offset during execution of the positioning in (D-2) when the position of an image (signal) at the time of measurement is desired to be acquired with high accuracy.

Next, the steps ((D-5) to (D-8)) of positioning based on image acquisition accompanied by FOV movement are described.

(D-5) Deciding Whether Moving the Position is Necessary or Not

Information as to whether image acquisition is carried out while moving the position is registered in advance and it is decided whether the position movement is executed or not. In the case that the position movement is not executed, the flow proceeds to the (D-4) processing. In the case of execution of position movement, the number of frames is set again, too.

(D-6) Moving the FOV Position

In accordance with the information acquired in advance in the registration processing, the position is moved.

(D-7) Acquiring an Image (Signal)

At the position moved to in (D-6), an image of a low frame is acquired.

(D-8) Making a decision as to whether acquisition of images for accumulation is completed

It is decided whether acquisition of images for accumulation is completed. Basically, it is decided whether the total number of sheets of frames of images in which patterns for accumulation of an image for measurement exist coincides with the number of sheets of frames set in an image for measurement. If the condition is not satisfied, the flow returns to the processing of (D-6).

(D-9) Processing of Accumulating Images for Measurement/Inspection

Images acquired in (D-6) to (D-8) are accumulated to produce an image for measurement. In this case, they may be summed up simply but in fear of influences such as the position accuracy of the device and changes in the shape in the process for measurement, it is preferable that positioning is again conducted between acquired images and then an accumulated image is produced. In addition, even to the positioning processing of (D-2), the processings (D-5) to (D-6) can be applied.

Here, a method for enabling positioning in (D-6) to realize with high accuracy is explained using FIG. 7. In the event that positions of a plurality of low frame images acquired in (D-6) to (D-8) are offset due to the position accuracy of the device or changes in the shape of an actually acquired pattern, it is considered that the shapes of the pattern of a measurement object vary when the accumulation is simply conducted without performing positioning. In order to eliminate this variation, the positioning is carried out again in (D-9); an accumulated image as the result of the positioning is, however, narrowed in an effective range by amounts of offsets of the respective images (a portion of dotted lines in the intermediate drawing of FIG. 7). When a measurement area designated for measurement exceeds this effective area, the measurement results can presumably be incorrect so that measures such as alleviation of conditions for measurement or changing of the measurement area are required and a notification of this effect needs to be issued to the user through error/warning in the GUI.

When the positioning is again conducted in (D-6) and an image for measurement is acquired, only a portion at which the images overlap becomes an effective range for measurement and, if the measurement conditions include a portion being not effective, a reaction such as issuing a warning to the user is executed.

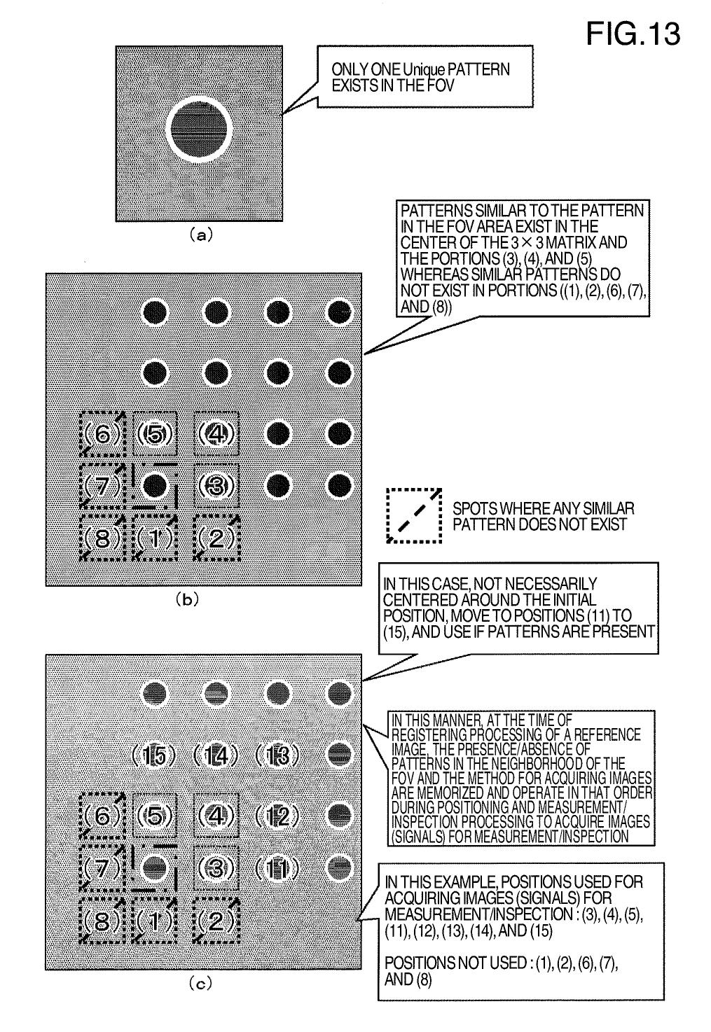

Next, an example of a method for measuring/inspecting the edge of a repetitive pattern is illustrated in FIG. 13 in the pattern exemplified in Part (b) of FIG. 3.

FIG. 13 is a diagram for explaining a plurality of methods for setting a FOV when only one hole exists in a FOV at measurement (Part (a) of FIG. 13) and the measurement object pattern is present at an edge of a repetitive pattern (a pattern surrounded by a dot-and-dash-line area (Part (b) of FIG. 13)).

In such an instance, the FOV is not needed to be the center for moving the position. When the amounts of position offsets at the positions (1) to (8) are calculated for the pattern of the FOV, it is understood that similar patterns do not exist at the positions (1), (2), and (6) to (8). In the present processing, when positioning is conducted through normalized correlation with the FOV position as the reference image and with a position as (1) as a detection image, for example, with a known method such as the correlation value becoming remarkably low as compared to the case of existence of a similar pattern, discrimination can be made as to whether a similar pattern exists.

Then, after making such a decision, directions in which patterns are considered to exist are detected and the positions (11) to (15), for example, are selected for images for accumulation (Part (c) of FIG. 13).

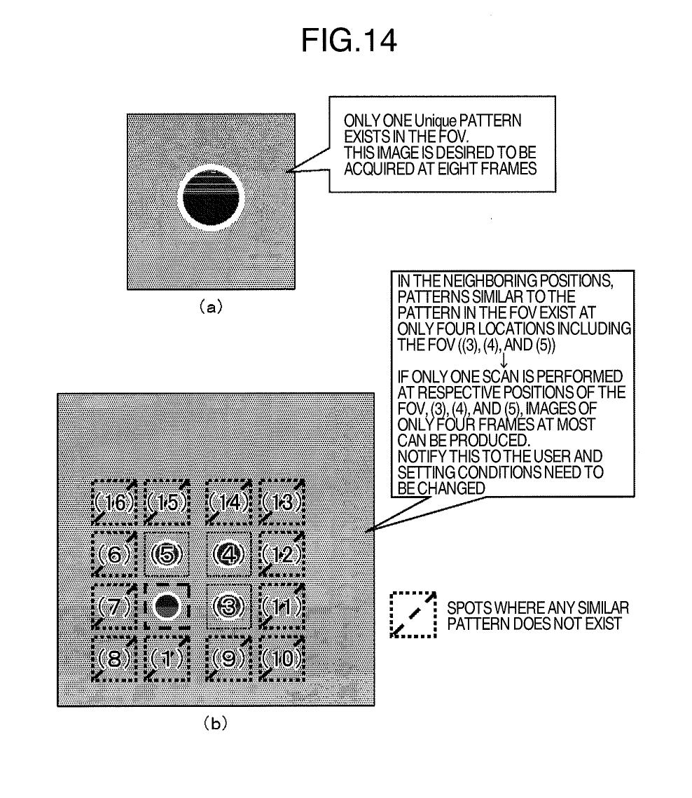

Further, a method is described below for dealing with a case when similar patterns around the FOV lack for production of images of the desired number of frame sheets as exemplified in FIG. 14. An explanation is given to an example where an image exemplified in Part (a) of FIG. 14 is desired to be acquired for eight frames while making the amount of irradiation of electron beam at each position rendered for one frame.

As exemplified in Part (b) of FIG. 14, the result of searching similar patterns around the FOV shows that similar patterns including the FOV exist at only four spots. In this case, acquisition of eight frames with images at four spots is impossible and electron beam irradiation for at least two frames at the respective spots needs to be conducted. Then, notification to the user must be issued through an error message, warning, or the like, informing the user of execution of the scan of two frames at the respective spots or urging the user to set as a FOV a location where similar patterns exist at eight spots at least in the neighborhood.

Further, in respect of measurement/inspection position offsets caused by the positioning accuracy and on the like, correction can be made using the present information.

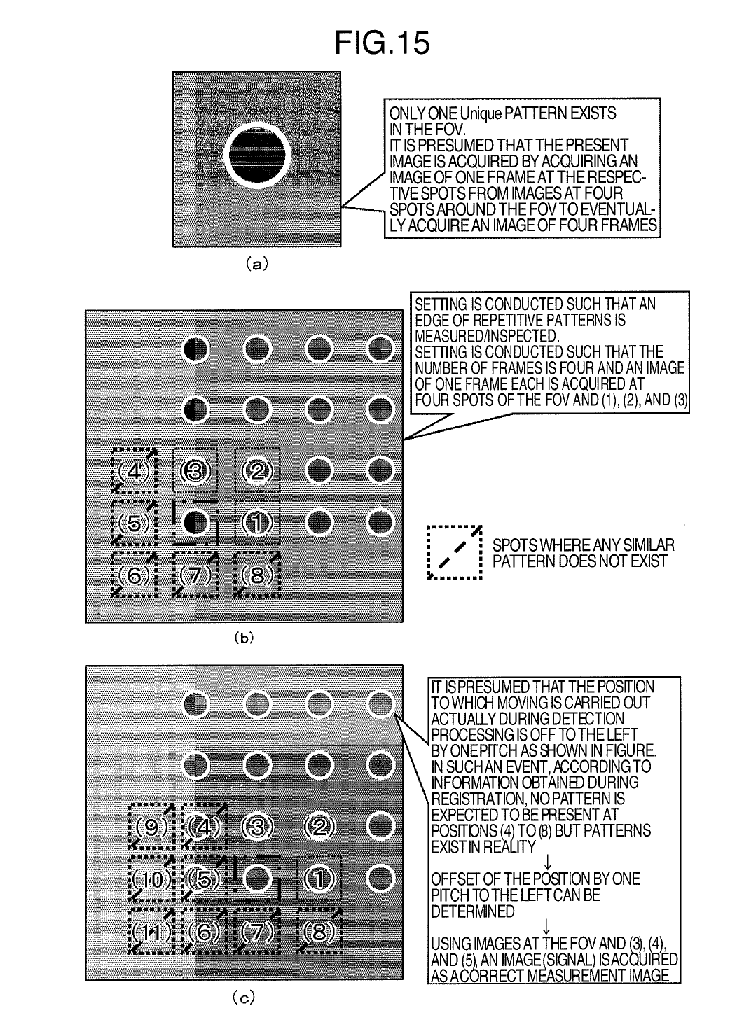

Then, an example of a processing of correction when the positions are off at the time of registration and in the actual detection processing is described with reference to FIG. 15.

In the present example, a unique pattern as exemplified in Part (a) of FIG. 15 is formed based on an image of four frames. First, an edge of repetitive patterns (a pattern surrounded by dot and dash lines in Part (b) of FIG. 15) is registered as a reference FOV. In an actual measurement image, however, only a single pattern is present within the FOV as exemplified in Part (a) of FIG. 15 and, therefore, it can not be determined with a FOV image. In the processing for registering a reference image for positioning, the condition of repetition of patterns around the FOV is examined by lowering the magnification as shown in Part (b) of FIG. 15. In this case, setting is done such that images are acquired frame by frame at clockwise pattern positions (1) to (3) from the FOV and accumulated. Further, at this time, images are also acquired with regard to areas (4) to (8) in Part (b) of FIG. 15 to investigate the presence/absence of patterns in advance.

When the positioning processing is performed, the position of the FOV after moving is off to the right by one pitch from a desired position as exemplified in Part (c) of FIG. 15 due to reasons such as the accuracy of position movement of the device and variations in samples to be inspected (a position surrounded by dot and dash lines in Part (c) of FIG. 15).

The positions (4) and (5) are known for the patterns to be absent at the time of the processing of registering conditions for positioning but, when a positioning processing is actually conducted, patterns are present at (4) and (5). Here, by further investigating areas (9) to (11) in Part (c) of FIG. 15, it is figured out that the patterns do not exist at these positions. Since any patterns are not present similarly at (6) to (8), it can be seen that the FOV is designated to be off by one pitch to the right and actually position (5) in Part (c) of FIG. 15 corresponds to the FOV to be measured. Accordingly, for an actual image for measurement/inspection, images at the FOV and positions (3) to (5) are determined to be accumulated, respectively (in case the present processing is not carried out, images at a position surrounded by dot and dash lines and (1) to (3) are used so that a pattern adjacent by one pitch is measured).

Through the present correction processing, a positional offset at the time of positioning depending on the positioning accuracy of the device and the like can be corrected. In addition, by using images of low frames at the respective positions which are acquired through the present processing, measurement can be conducted. In this case, when images used for measurement are saved, images of low frames at respective moved positions are also acquired in association with the accumulated image. For example, when four sheets of images of one frame are acquired, an average value of the case where measurements are conducted with respective images of one frame is set as a representative value of the measurement result. In addition, by calculating numerical values such as maximum/minimum values, maximum minus minimum, and standard deviation/variance and rendering them as representatives of measurement, average measurement results in the range measured during measurement image processing and variations of processings at the respective positions can also be measured.

According to the various embodiments set forth so far, by reducing the amount of electron beam irradiated on the pattern in the course of the processings of the sequence up to the pattern measurement/inspection (automatic focusing, positioning, and measurement/inspection), damages imposed on the pattern can be mitigated.

Next, a device and a system for carrying out the embodiments described above and computer programs (or a memory medium for memorizing the computer programs) executed thereby are described with reference to the drawings. More specifically, a device including a Critical Dimension-Scanning Electron Microscope: CD-SEM) which is a kind of measurement devices, a system, and computer programs realizable by them are described.

In addition, application to not only a device for measurement of dimensions of a pattern but also to a device for inspecting defects of the pattern is possible. Although in the following description an example using a SEM as embodying the charged particle beam device is described, it is not limited thereto and, for example, a focused ion beam (FIB) device, which scans an ion beam on a sample to form images, may be adopted as a charged particle beam device. Since an extremely high magnification is required in order to measure a pattern, for which refinement progresses, with high accuracy, however, using a SEM, which exceed a FIB device generally from the standpoint of the resolution, is desirable.

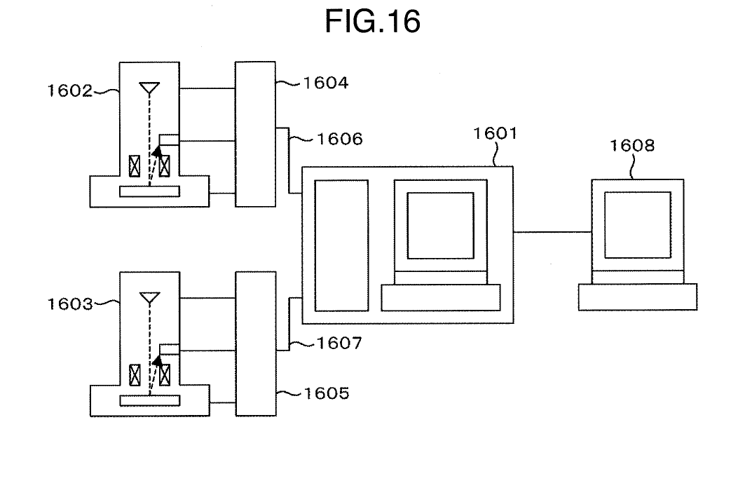

Illustrated in FIG. 16 is a system in which a plurality of SEM's are connected around a data management device 1601 at the center. Especially in the present embodiment, a SEM 1602 is adopted mainly to measure and inspect patterns of photo-masks and reticles used in semiconductor lithography processes and a SEM 1603 is mainly adopted to measure and inspect patterns transcribed to a semiconductor wafer through lithography using the above photo-masks or the like. The SEM's 1602 and 1603 do not differ remarkably from each other in the basic construction as an electron microscope but they are constructed, respectively, to correspond to differences in size of the semiconductor wafer and the photo-mask and differences in tolerance to electric charging.

Each of the SEM's 1602 and 1603 is connected with each of control units 1604 and 1605, respectively, so that control necessary for the SEM is executed. In each of the SEM's, an electron beam emitted from an electron source is focused by a plurality of stages of lenses and the focused electron beam is scanned on a sample one-dimensionally or two-dimensionally by a scanning deflector.

Secondary electrons (SE's) or backscattered electrons (BSE's) emitted from the sample due to the electron beam scanning are detected with a detector and are stored in a memory medium such as a frame memory in synchronism with the scan of the above scanning deflector. Image signals stored in the frame memory are accumulated by an arithmetic unit mounted in each of the control units 1604 and 1605. Incidentally, the scan by the scanning deflector can be carried out in an arbitrary size, at an arbitrary position, and in an arbitrary direction.

The control and the like as above are executed in the control units 1604 and 1605 of the respective SEM's and images and signals obtained as results of scanning of the electron beams are sent to the data management device 1601 via communication lines 1606 and 1607. Incidentally, while in the present example the control unit for controlling the SEM is described as being separate from the data management device adapted to perform measurement based on signals obtained by the SEM, it is not limited thereto; in the data management device, control of the device and a measurement processing may be performed in a lump or in each control unit control of the SEM and a measurement processing may be executed together.

Also, in the above data management device or the control unit, a program for execution of a measurement processing is memorized and measurement or operation is carried out according to the program. In addition, in a design data management device, design data of photo-masks used for a semiconductor fabrication process (hereinafter, may simply be referred to as masks) and wafers are memorized. The design data are expressed, for example, in the GDS format or the OASIS format and memorized in a predetermined format. It is to be noted that, if software adapted to display the design data can display its format type and can handle as shape data, the kind of the design data does not matter. Alternatively, design data may be memorized in a memory medium provided separately from the data management device.

Further, the data management device 1601 has a function to produce a program (recipe) for controlling an operation of a SEM based on design data of a semiconductor, thus functioning as a recipe setting unit. More specifically, a program is produced which is adapted to set design data, contour data of a pattern, or desired measurement point on design data applied with simulation, positions at which processings such as auto-focus, auto astigmatism correction, and addressing necessary for the SEM are executed, and the like and adapted to control the sample stage, the deflector, and the like of the SEM automatically. Incidentally, a template matching method using a reference image called a template is a method in which a template is moved in a search area for searching a desired spot to specify a spot where the degree of coincidence with the template is highest or the degree of coincidence becomes equal to or more than a predetermined value in the search area. The control units 1604 and 1605 execute pattern matching based on a template which is one of pieces of registered information of a recipe.

Further, a focused ion beam device for irradiating helium ions, liquid metal ions, or the like on the sample may be connected to the data management device 1601. Furthermore, a simulator 1608 for simulating a result of a pattern based on the design data may be connected to the data management device 1601 so that a simulation image obtained by the simulator is made into the GDS format which in turn may be used in place of the design data.

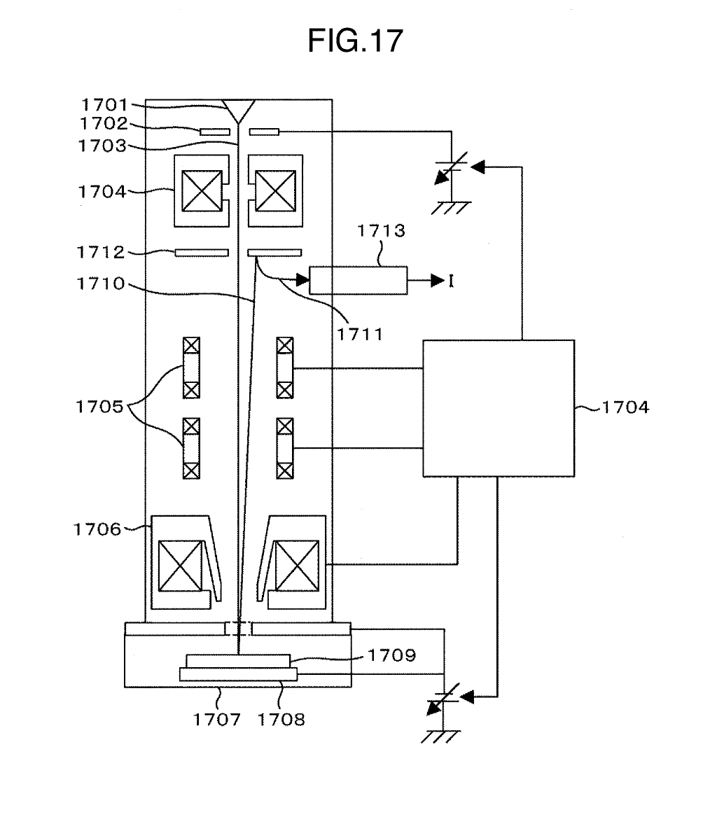

FIG. 17 is a schematic construction diagram of a scanning electron microscope. An electron beam 1703 extracted from an electron source 1701 with an extraction electrode 1702 and accelerated by an accelerating electrode, which is not shown, is focused by a condenser lens 1704, which is one form of focusing lens, and thereafter scanned on a sample 1709 one-dimensionally or two-dimensionally by a scanning deflector 1705. The electron beam 1703 is decelerated by a negative voltage applied to an electrode built in a sample stage 1708 and is focused by the action of an objective lens 1706 so as to be irradiated on the sample 1709.

As the electron beam 1703 is irradiated on the sample 1709, electrons 1710 such as secondary electrons and backscattered electrons are emitted from the irradiated spot. The thus emitted electrons 1710 are accelerated in the direction toward the electron source by accelerating effect based on the negative voltage applied to the sample, thereby impinging on a conversion electrode 1712 which in turn generates secondary electrons 1711. The secondary electrons 1711 given off from the conversion electrode 1712 are captured by a detector 1713 and an output I of the detector 1713 changes by the amount of the captured secondary electrons. In accordance with the output I, a brightness of a display unit, which is not shown, changes. When forming a two-dimensional image, for example, an image of a scan area can be formed by synchronizing the deflection signal to the scanning deflector 1705 with the output I of the detector 1713. The scanning electron microscope exemplified in FIG. 17 is also provided with a deflector (not shown) for moving a scan area of the electron beam. The deflector is used for forming images or the like of patterns of an identical shape existing at different positions. This deflector is also called an image-shift deflector which enables the FOV position to move without performing sample movement with the sample stage and the like. In the present embodiment, it is used for positioning the FOV to a plurality of repetitive patterns or the like. Alternatively, the image-shift deflector and the scanning deflector may be integrated to a common deflector and a signal for image-shifting and a signal for scanning may be superposed with each other to be supplied to the deflector. For the sake of making magnifications in the X direction and the Y direction identical in an image displayed on a square-shaped SEM image display area (not shown) in the display unit, the deflector for scanning scans the electron beam in such a manner that lengths in the X direction and the Y direction of the scan area are rendered constant. When an aspect ratio of the display area is not constant, magnifications in the X direction and the Y direction can always be made constant by setting the lengths in the X direction and the Y direction in accordance with the aspect ratio.

Incidentally, in the example of FIG. 17 an instance is explained in which electrons emitted from the sample are converted once by the conversion electrode but in no way it is limited to this configuration; a detection surface of an electron multiplier tube or a detector, for example, can be arranged on the trajectories of accelerated electrons.

The control unit 1604 controls the individual constituent components of the scanning electron microscope and also has a function to form an image based on detected electrons and a function to measure a pattern width of a pattern formed on the sample based on an intensity distribution of detected electrons called a line profile. Further, a frame memory, which is not shown, is built in the control unit 1604 and the frame memory stores signals such as images acquired in a unit of one-dimensional or two-dimensional scan in a unit of one scan.

Further, the control unit 1604 includes an arithmetic unit for accumulating signals such as images acquired in a unit of a frame. While in the present embodiment the control unit 1604 is a signal processing unit which performs accumulation of images or the like, it is not limited thereto and, for example, the frame memory and the arithmetic unit for accumulation of images or the like may be provided in the data management device 1601 to make it to serve as the signal processing unit. Namely, the signal processing unit may be replaced with a memory medium and an arithmetic unit which are connected to the scanning electron microscope via a network or the like.

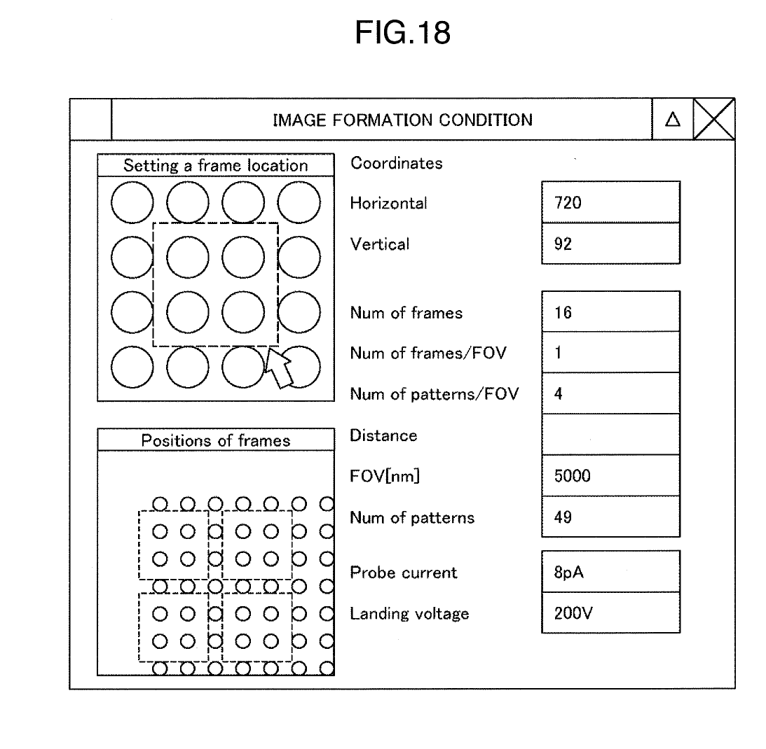

FIG. 18 is a diagram for explaining an example of a screen (GUI) for setting device conditions at creation of a recipe which is displayed on a display unit connected to the data management device 1601. The GUI exemplified in FIG. 18 is for setting a plurality of FOV positions subject to the accumulation on layout data of design data of a semiconductor device. Based on position information on the sample set on the GUI (coordinate information) or the like, the data management device 1601 reads data corresponding to the set position or the like out of the design data and displays layout information of that part on the screen.

Further, in this phase, image signals necessary for accumulation (the number of frames), a range (size) of a FOV, the number of patterns contained within one FOV, the distance between frames subject to accumulation (setting of an upper-limit value or a lower-limit value being permissible), and the like can be inputted. Also, the size of a FOV (or the number of patterns contained within a FOV) may be based either on range designation on the layout data by a pointing device, which is not shown, or the like or on input of numerical values. Registered in the data management device 1601 is a program according to which by setting several conditions on the GUI other conditions are determined automatically or the previously-described error message is issued.

More specifically, by setting the number of necessary frames and the size of a FOV, a decision can be made as to whether such setting is possible or not. Since object patterns and the number of the patterns contained within a FOV can be specified by setting the FOV, it is decided whether such setting is possible by referencing to the design data for such information. Since the number of specified patterns and conditions for their arrangement are stored in advance in the design data, it can be known that, for example, 49 patterns being set, which are within a FOV, are present including patterns in the FOV and setting of four frames is possible when four patterns are set to be included in a FOV according to the example of FIG. 18. In other words, because the number of frames of sixteen sheets set on the GUI in FIG. 18 cannot be acquired, an error message is issued or the number of required frames of one FOV (four frames in this example) is displayed in such an event. By providing a program to make such a decision, a recipe can be created with which occurrence of shrink of the sample and attachment of contamination thereon can be suppressed while mitigating the load imposed upon creation of the recipe.

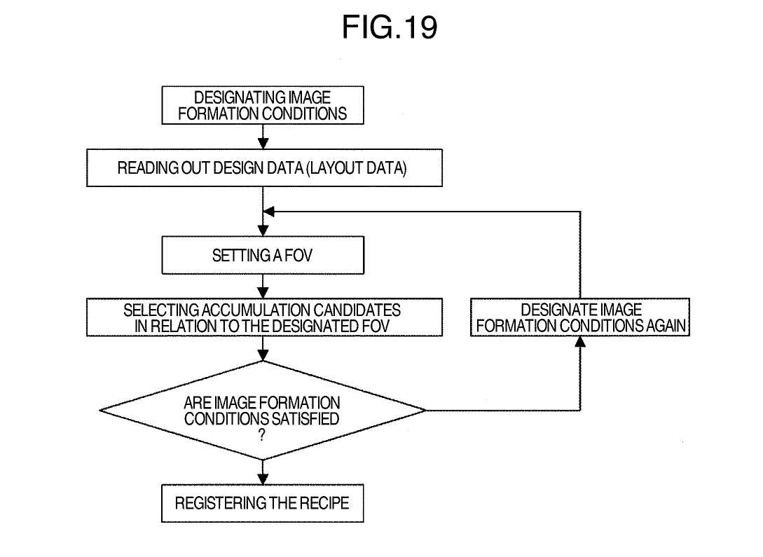

FIG. 19 is a flowchart for explaining an example of a recipe creation process. First, conditions for image formation (the position of a FOV, the number of frames, and the like, which are items necessary and settable on the GUI exemplified in FIG. 18) are designated and based on the designated information of coordinates or the like design data corresponding to the part is read out from the memory medium in which the design data is memorized. The readout design data is displayed on a display unit connected to the data management device 1601 or the like and the size of the FOV, magnification, accurate position, and the like are set on the layout data.

At this stage, an operation for calculating how many FOV's of accumulation objects are present in respect of a reference FOV can be possible; if candidates equal to or more than the set value are present, desired candidates for accumulation are selected among them and, in case a desired number of designated accumulation candidates in relation to the reference FOV can not be obtained, the image formation conditions, the FOV size, and the like are set again.

The conditions determined through the steps above are registered as a recipe. By setting a plurality of FOV's through these steps, conditions for image formation capable of suppressing occurrence of shrink or the like can be easily determined.

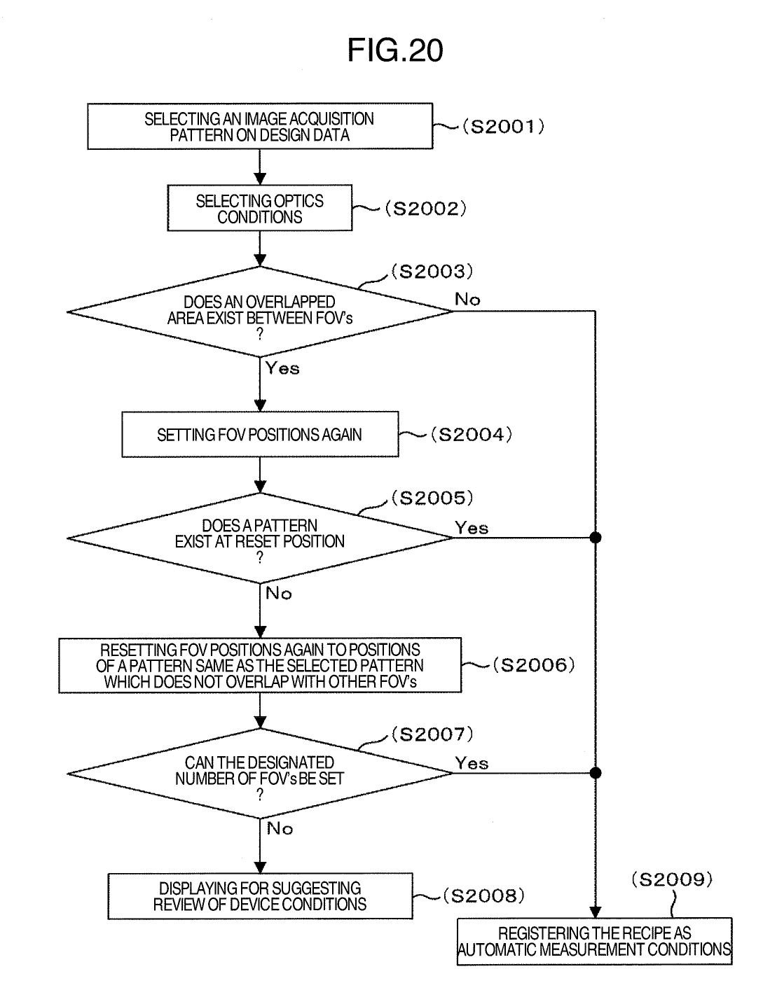

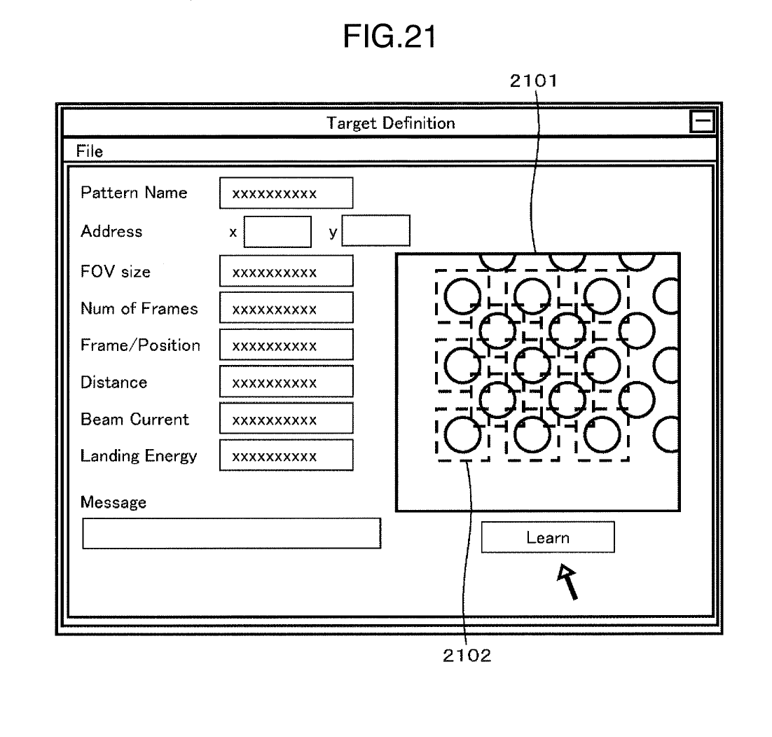

FIG. 20 is a flowchart showing another example of the recipe creation process and FIG. 21 is a diagram illustrating an example of a GUI for setting to create a recipe in accordance with the flowchart of FIG. 20. In this example, an instance is explained in which a pattern name or an address of a pattern is inputted in order to set a desired image acquisition position on the design data but it is not limited thereto; a different setting method may be applied as long as an image acquisition position can be specified. Further, selection of only one pattern may be executed so that patterns of the same shape as that of the selected pattern may be selected automatically; or two or more patterns may be selected so that patterns of the same shapes as those of the selected patterns may be selected at intervals of the two selected patterns by the number of those designated later. In Step 2001, an image acquisition position (a pattern of an acquisition object) is selected on the design data based on the designated conditions.

Next, in Step 2002, the optics conditions of the scanning electron microscope (for example, the size of the FOV (FOV size), the number of frames to be acquired (Num of Frames), the number of tolerable frames at one pattern position (Frame/Position), the beam current (Beam Current), the landing energy of the beam on the sample (Landing Energy), and the like) are set.

Based on the size of the FOV and the number of frames which are set candidates 2102 for FOV's to be acquired are arranged automatically on the layout data displayed based on the setting described above within a setting screen 2101. Arrangement of the plurality of candidates for FOV's is supposed to be carried out in accordance with a predetermined rule and, for example, it is conceivable that a single pattern is selected and patterns having the same shape as that of the pattern are extracted by the number of frames being set as described previously. Since the pattern shape information is registered in the design data, the aforementioned setting may be conducted based on that information.

Next, it is decided whether adjoining FOV's partly overlap with each other in Step 2003. As explained previously, with the FOV's overlapped, the beam is irradiated plural times on the overlapped portion and, therefore, the overlapped area is desired not to be provided in order to suppress shrink of the patterns or the like. The present example relates to a method of creating a recipe in which device condition setting for a scanning electron microscope which the operator desires and which makes capable of suppressing shrink can be easily implemented.

When it is determined an overlapped area exists in Step 2003, FOV positions are set again (Step 2004). Resetting is done by changing the FOV positions based on a predetermined rule. For example, when the distance between patterns of the same shape is d, the positions of the FOV's may conceivably be changed so that the distance between the FOV's may be 2 d. Namely, by setting the FOV positions by skipping one pattern, it is adjusted so that the FOV's won't mutually overlap.

Next, it is decided whether or not a pattern is present at the reset FOV positions (Step 2005). With the distance between the FOV's adjusted to be doubled at Step 2004, there is a possibility that the FOV's are positioned at positions where no pattern is present when an edge of arrangement of hole patterns is used as a reference as exemplified in FIG. 21, for example. Accordingly, in Step 2005 the reset FOV positions are compared to the design data to make a decision as to whether patterns are included at the respective set positions without exception.

When it is determined through this decision that no pattern is contained at any FOV position, resetting of the FOV positions is conducted again based on the design data (Step 2006). In this case, the FOV positions are set at positions of a pattern which are categorized as a pattern having the same shape as that of the designated pattern. Incidentally, Step 2006 may be located next to Step 2003.

Next, in Step 2007, it is decided based on the processings as above whether or not setting of FOV's can be done for the designated number of frames and an indication or the like suggesting review of the device conditions may be displayed on a message column (Step 2008) when it is not done.

As the case of failing in setting, such a case that the size of the FOV is too large or that the number of set frames per se is larger than the number of patterns is conceivable and, accordingly, the operator can adjust the device conditions based on such a message.

When appropriate conditions can be searched through the above steps, the conditions are set as a recipe as automatic measurement conditions (Step 2009).

According to the computer program or the like which causes the arithmetic unit to execute the processings exemplified in FIG. 20, the device condition setting can be performed while considering a balance between the device conditions of a scanning electron microscope the operator intends and the device condition capable of mitigation of shrink.

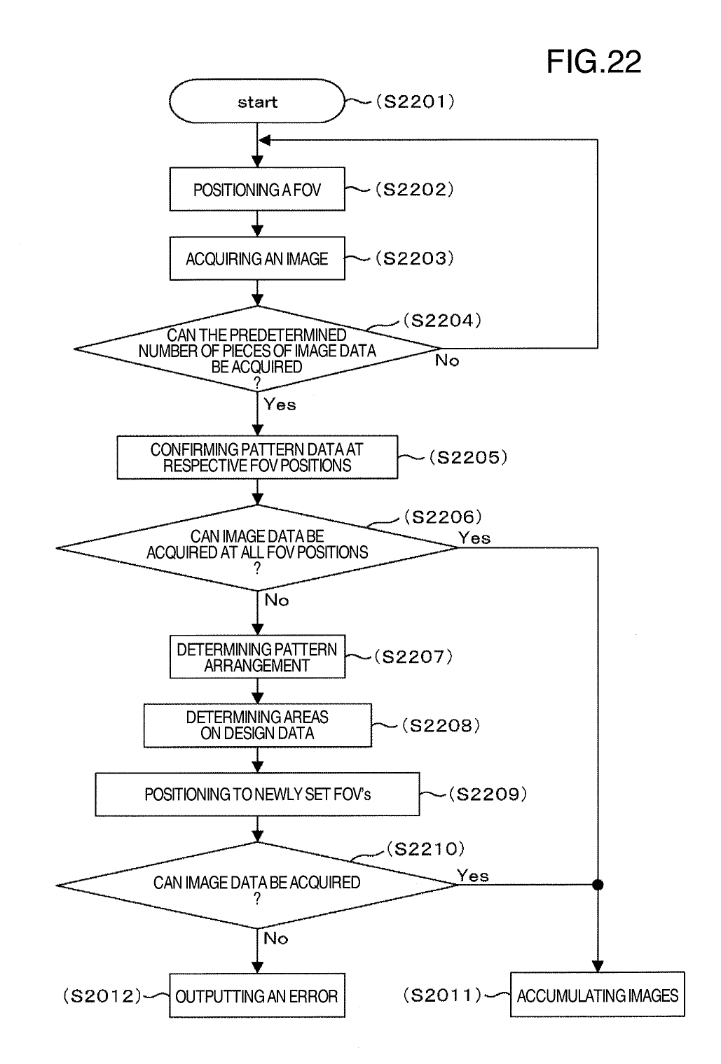

Next, processing steps of a scanning electron microscope for performing measurement of patterns in accordance with the recipe are explained with reference to a flowchart exemplified in FIG. 22. First, after turning on the device (Step 2201), the stage and the deflector of the scanning electron microscope are controlled so that a FOV is located at a set position on the sample (Step 2202). Step 2202 and Step 2203 are executed repetitively by the necessary number of frames (Step 2204) and, when the necessary number of frames of image data can be acquired, it is decided whether the image data is properly acquired at respective FOV's (Steps 2205, 2206).

A decision as to whether the image data at each position can be obtained is made based on a decision as to whether the acquired signal satisfies predetermined conditions. For example, when a predetermined pattern is included in a FOV, the above conditions are determined to be satisfied.

Next, when it is determined that pattern data cannot be obtained at one or more FOV positions, moving to a new FOV is conducted and a processing for acquiring an image is carried out. Specifically, a decision is made first on the arrangement of acquired patterns. To give an explanation more specifically, in acquiring images of FOV's arranged in the form of, for example, a matrix of five in the X direction and five in the Y direction, if no image data is contained in one column on the left side of5×5 matrix, the5×5 arrangement of FOV's is presumed as being off to the left by one column of the patterns. Accordingly, in Step 2207, the arrangement of the patterns is decided and new FOV's may be set based on the decision result (Step 2209). In the case of this example, since it can be determined that the pattern arrangement is off to the left by one column of the patterns, it can be figured out that the patterns to originally be acquired exist inversely to the right side of the pattern arrangement. Therefore, the FOV is moved to those positions to acquire images. In this example, relationships between information of new FOV positions and the pattern arrangement may be registered in advance and it may move to the new FOV's based on the registered information.

Incidentally, if the arrangement of patterns is complicated or the like, the design data may also be referenced for specifying an amount and a direction of an offset of the FOV (Step 2208). As described above, when it is determined that pieces of image data of the predetermined number are acquired, the acquired images are accumulated to form an accumulated image (Step 2011). In the event that image data cannot be acquired even going through the above steps, reasons such as the coordinates being off significantly can be considered and by generating error information early recovery of the device is urged (Step 2012).

According to the computer program or the like which causes the arithmetic unit to execute the processings as exemplified in FIG. 22, the rate of automation when an image is acquired at the conditions where the influence of shrink can be suppressed can be improved.

### REFERENCE SIGNS LIST

1601 Data management device
1602, 1603 SEM
1604, 1605, 1610 Control unit
1606, 1607 Communication line
1608 Simulator
1701 Electron source
1702 Extraction electrode
1703 Electron beam
1704 Condenser lens
1705 Scanning deflector
1706 Objective lens
1707 Sample chamber
1708 Sample stage
1709 Sample
1710 Electrons
1711 Secondary electrons
1712 Conversion electrode
1713 Detector

1. A signal processing method in a charged particle beam device for forming an accumulated signal by accumulating signals obtained by scanning a charged particle beam comprising the steps of:
scanning said charged particle beam at different positions on a sample;
accumulating signals obtained through scans at said different positions; and
forming said accumulated signal.

2. A signal processing method in a charged particle beam device according to claim 1,
wherein scanning said charged particle beam is conducted to patterns of an identical shape on design data existing at different positions on said sample.

3. A signal processing method for a charged particle beam according to claim 1, based on said signals obtained by accumulation further comprising the steps of:
adjusting a focus of said charged particle beam;
forming an image for positioning; and/or
measuring or inspecting a pattern formed on said sample.

4. A signal processing method for a charged particle beam according to claim 1,
wherein scanning said charged particle beam is conducted to patterns of an identical shape on design data existing at different positions on said sample; and
wherein said patterns of an identical shape are repetitive patterns formed on said sample.

5. A signal processing method for a charged particle beam according to claim 1,
wherein scanning said charged particle beam is conducted to patterns of an identical shape on design data existing at different positions on said sample; and
wherein said patterns of an identical shape are line patterns.

6. A signal processing device of a charged particle beam device, which comprises
a memory medium for storing signals obtained by scanning a charged particle beam; and
an arithmetic unit for accumulating signals stored in said memory medium:
wherein said arithmetic unit scans said charged particle beam at different positions on a sample, accumulates signals obtained through scans at said different positions, and forms said accumulated signal.

7. A signal processing device of a charged particle beam device according to claim 6,
wherein scanning said charged particle beam is conducted to patterns of an identical shape on design data existing at different positions on said sample.

8. A signal processing device for a charged particle beam according to claim 6,
wherein, based on said signal obtained by accumulation, a focus of said charged particle beam is adjusted, an image for positioning is formed, and/or a pattern formed on said sample is measured or inspected.

9. A signal processing device for a charged particle beam according to claim 6,
wherein scanning said charged particle beam is conducted to patterns of an identical shape on design data existing at different positions on said sample; and
wherein said patterns of an identical shape are repetitive patterns formed on said sample.

10. A signal processing device for a charged particle beam according to claim 6,
wherein scanning said charged particle beam is conducted to patterns of an identical shape on design data existing at different positions on said sample; and
wherein said patterns of an identical shape are line patterns.
